(19) United States
(12) Patent Application Publication
(10) Pub. No.: US 2007/0096721 A1
(43) Pub. Date: May 3, 2007

(54) Apparatus for verifying a mobile communication system and method thereof

(75) Inventor: Dae-Soo Ha, Suwon-si (KR)

Correspondence Address: DILWORTH & BARRESE, LLP, 333 EARLE OVINGTON BLVD., SUITE 702, UNIONDALE, NY, 11553, US

(73) Assignee: SAMSUNG ELECTRONICS CO., LTD., Suwon-si (KR)

(21) Appl. No.: 11/582,689

(22) Filed: Oct. 17, 2006

(30) Foreign Application Priority Data
Oct. 18, 2005 (KR) 2005-0097847

(51) Int. Cl. G01R 31/28

(52) U.S. Cl. 324/158.1

(57) ABSTRACT

An apparatus for verifying a mobile communication system and a method thereof are provided. The mobile communication system includes boards that provide functions for constituting the mobile communication system, and a testing and verifying apparatus for transmitting a test mode change request signal to a board to be verified among the boards and for examining the internal characteristics and the operation state of the board to be verified. Therefore, it is possible to reduce hardware load and software load when the apparatus for verifying the mobile communication system is realized, to immediately cope with problems that occur in the mobile communication system, and to thus effectively use the mobile communication system.

### PRIORITY

This application claims priority under 35 U.S.C. § 119 to an application filed in the Korean Intellectual Property Office on Oct. 18, 2005 and assigned Serial No. 2005-97847, the contents of which are incorporated herein by reference.

### BACKGROUND OF THE INVENTION

1. Field of the Invention

The present invention relates generally to a mobile communication system, and in particular, to a testing and verifying apparatus for rapidly analyzing the cause of problems in the system to solve the problems, and a method thereof.

2. Description of the Related Art

A mobile communication system is comprised of a plurality of boards that operate their unique functions. For example, the boards included in the base station are comprised of a network synchronization board, a processor board, a link board, a MODEM block board, and an alarm board in accordance with the characteristics of the system. Also, the boards are comprised of various parts in accordance with the functions provided by the boards.

When the mobile communication system is comprised of the boards, the test environments suitable for the operation characteristics of the mobile communication system are utilized to check the operation state of the mobile communication system. That is, the operation states (for example, levels) of the boards that constitute the mobile communication system are examined.

The operation states of the boards are commonly examined by a boundary scan test (BST) process for examining the electrical characteristics of the main parts mounted on the boards and by a board verifying process for identifying whether the boards correctly operate as designed.

In the BST process, the joint test action group (JTAG) pins of all devices constitute one loop using the JTAGs provided to the devices. Then, the signals received from the devices are measured to determine whether the devices are operating normally. Here, the JTAGs mean communication channels of a standard specification for controlling the devices.

In the BST process, the only basic functions provided by a device enterprise are checked. Therefore, the board verifying process is performed in order to check detailed functions or operations.

Since the board verifying process must be utilized to examine all functions in the devices and boards, the functions of programmable logics such as a field-programmable gate array (FPGA) are used for testing the boards.

FIG. 1 illustrates the structure of a conventional test apparatus for verifying a mobile communication system.

As illustrated in FIG. 1, in order to test a test board 100, a test JIG 110 is required. The test JIG 110 is designed to provide clocks or signals required for the boards, so that the test board 100 must be mounted in the corresponding position of the test JIG 110. At this time, the clocks or signals required for the boards vary. Therefore, the test JIG 110 exists in each of the boards.

The test JIG 110 is connected to a JTAG test apparatus 130 through a BST cable in order to BST verification of the test board 100 and is connected to a debugging computer 160 through an FPGA fusing cable 140 in order to receive a test only image for verifying the test board 100. Also, the test JIG 110 is connected to the debugging computer 160 through a Universal Asynchronous Receiver/Transmitter (UART)/Ethernet (ETH) debug cable 150 so that a user can check state information on the test board 100. Here, the test program checks the detailed operations of the board.

The debugging computer 160 stores the test only image for verifying the test board 100 to transmit the test only image to the test JIG 110 when the board is verified. Also, the debugging computer 160 collects the state information on the test board 100 that is received from the test JIG 110 so that the user can check the state information.

When the above-described mobile communication system is tested and verified, since there are limitations on the spaces in which the boards included in the mobile communication system are mounted, it is difficult to attach cables (such as the BST cable, the FGPA fusing cable, and the UART/ETH debug cable) required for verifying the board. Also, a process of setting the cables to have the same environment must be repeated, the devices in the boards must be set, and the test only image must be downloaded every test step so that it is difficult to establish the environments of verifying the mobile communication system.

### SUMMARY OF THE INVENTION

An aspect of the present invention is to substantially solve at least the above problems and/or disadvantages and to provide at least the advantages below. Accordingly, an aspect of the present invention is to provide an apparatus for providing a test slot for simplifying limitation items generated in processes of testing and verifying a mobile communication system and a program memory required therefore and a method thereof.

Another aspect of the present invention is to provide an apparatus for performing verifying without using additional cables by designing boards to be basically latticed in a mobile communication system, by providing a memory for storing information items and test images in accordance with the characteristics of the boards, and by adding a test apparatus for providing environments suitable for the boards, and a method thereof.

In order to achieve the above objects, according to one aspect of the present invention, an apparatus for verifying a mobile communication system includes a test slot in which boards that constitute the mobile communication system are positioned to change the boards to a testing and verifying mode in accordance with a test mode request signal received from a testing and verifying apparatus, and a testing and verifying apparatus for transmitting a test mode change request signal to a board to be verified among the boards and for examining the internal characteristic and the operation state of the board changed to the testing and verifying mode.

According to another aspect of the present invention, a method of operating a testing and verifying apparatus for verifying a mobile communication system includes transmitting a test mode change request signal to a predetermined board when the board is tested and verified, determining whether the board that received the test mode change request signal is changed to a testing and verifying mode, and examining the internal characteristic and the operation state of the board in accordance with a testing and verifying method when the board is changed to the testing and verifying mode.

### BRIEF DESCRIPTION OF THE DRAWINGS

The above and other objects, features and advantages of the present invention will become more apparent from the following detailed description when taken in conjunction with the accompanying drawings in which:

FIG. 1 illustrates the structure of a conventional test apparatus for verifying a mobile communication system;

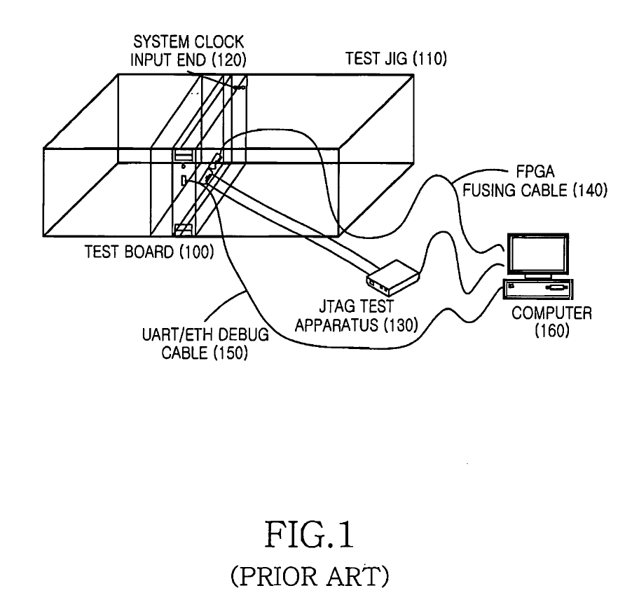

FIG. 2 illustrates the structure of a test apparatus for verifying a mobile communication system according to the present invention;

FIG. 3 is a block diagram of a test apparatus for verifying the mobile communication system according to the present invention; and

FIG. 4 illustrates a flowchart for verifying a mobile communication system according to the present invention.

### DETAILED DESCRIPTION OF THE PREFERRED EMBODIMENTS

Preferred embodiments of the present invention will be described herein below with reference to the accompanying drawings. In the following description, well-known functions or constructions are not described in detail since they would obscure the invention in unnecessary detail.

The present invention provides a technique for verifying boards included in a mobile communication system without using an additional test apparatus in the mobile communication system. That is, the present invention provides a technique for verifying boards mounted in a rack without using an additional test apparatus by storing information items and images required for testing and verifying the boards in the rack designed to be basically latticed in the mobile communication system and by adding a testing and verifying apparatus for controlling the testing and verifying of the boards and for collecting the testing and verifying results. Here, the rack is a latticed structure in which the boards are mounted in the mobile communication system. The boards include a network synchronization board, a processor board, a link board, a MODEM block board, and an alarm board.

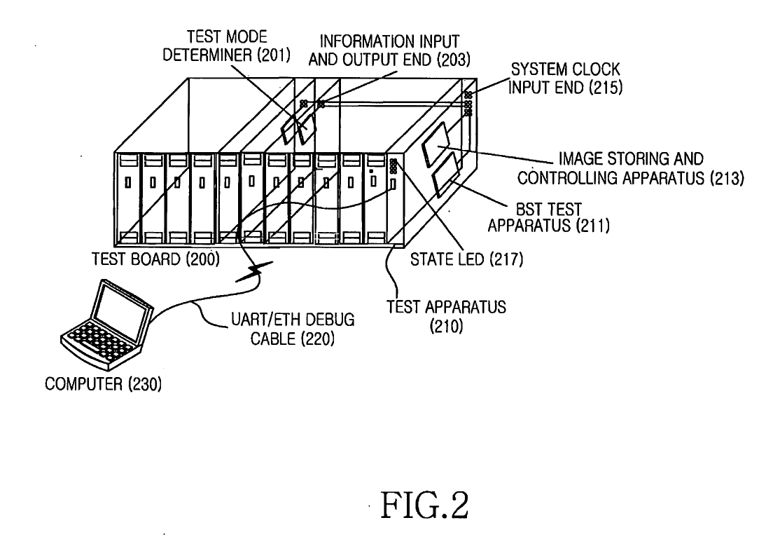

FIG. 2 illustrates the structure of a test apparatus for verifying a mobile communication system according to the present invention.

As illustrated in FIG. 2, the rack of the mobile communication system includes a test apparatus 210 for testing and verifying the boards 200 mounted in the rack.

The rack is connected to a debugging computer 230 by a Universal Asynchronous Receiver/Transmitter (UART)/Ethernet (ETH) debug cable 220. That is, the rack outputs the testing and verifying results of the boards 200 collected by the test apparatus 210 through the UART debug cable 220 to the debugging computer 230 so that a user can check the testing and verifying results of the boards 200.

The boards 200 are mounted in the rack, which is designed to be basically latticed as illustrated in FIG. 2 to perform a normal operation at normal times. Then, when a test mode change request signal is received from the test apparatus 210, the boards 200 are changed to a test mode. At this time, each of the boards 200 includes a test mode determiner 201 for changing the boards to the test mode when the test mode change request signal is received from the test apparatus 210. That is, each of the boards 200 is changed to the test mode in accordance with the control of the test mode determiner 201.

The test apparatus 210 receives system information from the alarm board to transmit the test mode change request signal to the test mode determiner 201 when an erroneous operation is generated by the mobile communication system or when a specific board is requested to be tested and verified.

Also, the test apparatus 210 includes a boundary scan test (BST) test apparatus 211, an image storing and controlling apparatus 213, a system clock input end 215, and a state light emitting diode (LED) 217 in order to test and evidence the boards mounted in the rack.

The BST test apparatus 211 selects the BST signals of boards to be tested and verified among the BST signals connected to the boards 200 to check the internal characteristics of the boards requested to be tested and verified.

The image storing and controlling apparatus 213 totally manages information items required for testing the operation states (for example, levels) of the boards 200 and test only images (for example, a field-programmable gate array (FPGA) image). Also, the image storing and controlling apparatus 213 collects the entire board operation states to transmit the collected board operation states to the debugging computer 230 through the UART/ETH debug cable 220.

The state LED 217 represents the test results of the test boards 200.

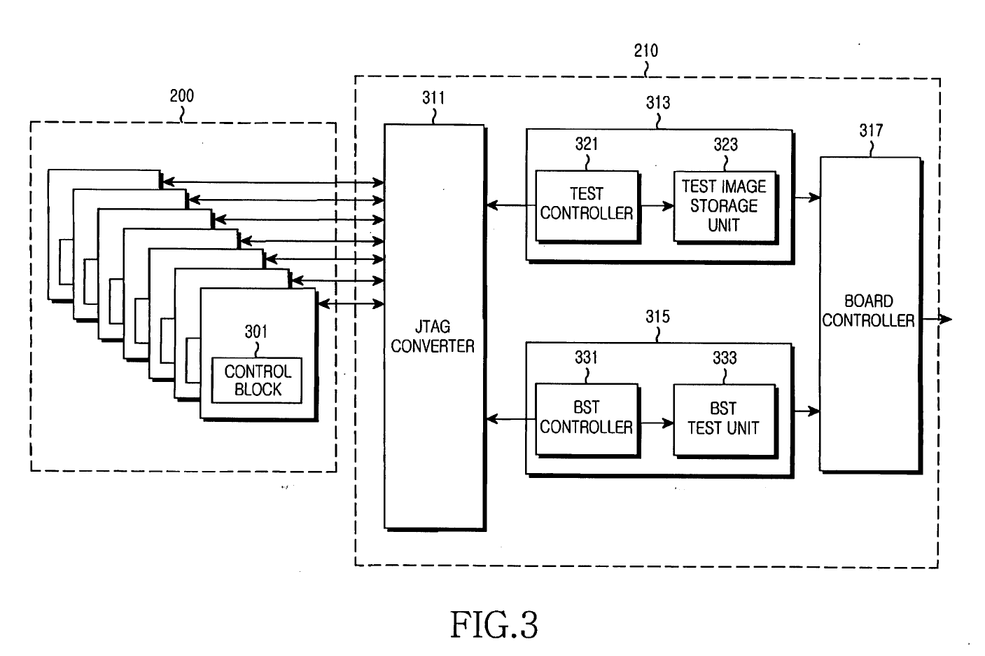

FIG. 3 is a block diagram of a test apparatus for verifying the mobile communication system according to the present invention. Hereinafter, the structure of the test apparatus 210 of FIG. 2 will be described in detail.

As illustrated in FIG. 3, the test apparatus 210 includes a joint test action group (JTAG) converter 311, a board verifying apparatus 313, a BST test apparatus 315, and a board controller 317.

The JTAG converter 311 connects the test apparatus 210 and the boards to be tested and verified among the boards 200 mounted in the rack to each other to transmit a signal for performing testing and verifying from the test apparatus 210 to the boards to be tested and verified. At this time, the JTAG converter 311 connects the test apparatus 210 and the boards to each other using a JTAG chain. For example, when the test mode change request signal is transmitted in order to test and evidence a first board among the boards 200 mounted in the rack, the JTAG converter 311 connects the test apparatus 210 and the first board to each other.

Here, when the test mode change request signal is received from the test apparatus 210, the board is changed to the test mode in accordance with the control of a control block 301 included in each of the boards 200. That is, the control block 301 monitors the signal input from the test apparatus 210 to change the corresponding board from a common mode to the test mode in accordance with the signal. When the test mode change request signal is received, the control block 301 requests the central processing unit (CPU) of the board to operate a test program. That is, the control block 301 is the same as the test mode determiner 201 of FIG. 2.

The board verifying apparatus 313 includes a test controller 321 and a test image storage unit 323.

The test image storage unit 323 stores the test only images of the boards 200 that constitute the mobile communication system. Here, the test only images are generated to be suitable for the characteristics of the boards in order to examine the operation states of the boards 200.

The test controller 321 controls the images of the boards to be tested and verified among the test only images of the boards 200 to be selected and transmitted so that the operation states of the boards are checked. At this time, the test controller 321 receives information items on the boards to be tested and verified from the board controller 317.

The BST test apparatus 315 includes a BST controller 331 and a BST test unit 333.

The BST controller 331 controls the BST test unit 333 to be connected to the board to be BST tested. The BST test unit 333 connects the BST tested and verified board and a JTAG channel to each other in accordance with the control of the BST controller 331 to perform BST verifying. That is, the BST test unit 333 checks the internal characteristics of the boards to be BST tested and verified.

The board controller 317 collects state information items on the tested and verified boards to transmit the state information items to the debugging computer 230. Also, the board controller 317 provides the state information items on the boards to the board verifying apparatus 313 and the BST test apparatus 315. That is, the board controller 317 provides information items on the boards to be tested and verified to the board verifying apparatus 313 and the BST test apparatus 315.

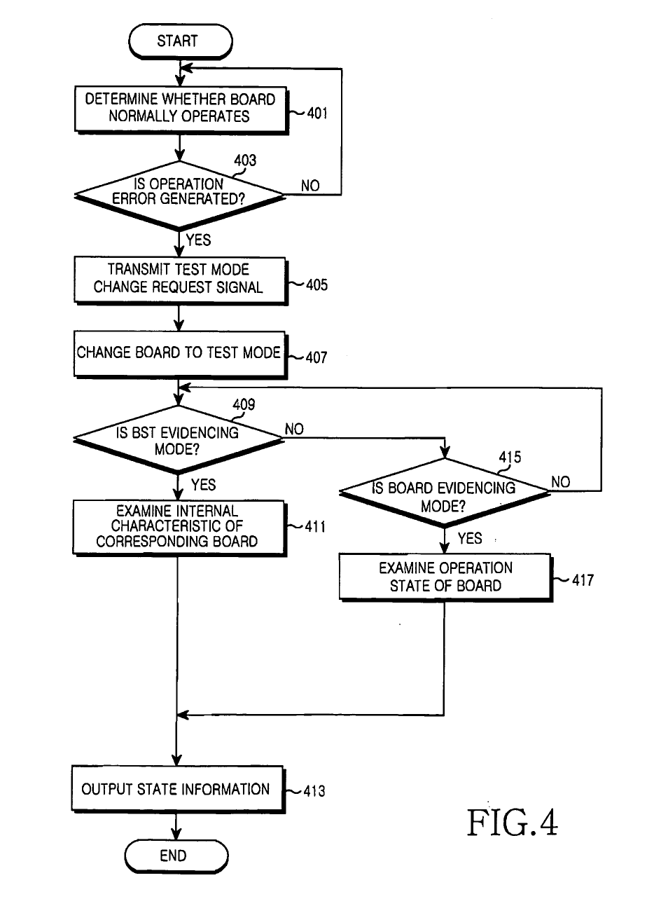

FIG. 4 illustrates a flowchart for verifying a mobile communication system according to the present invention. Hereinafter, it is assumed that an erroneous operation is generated by the mobile communication system and that the mobile communication system is verified.

Referring to FIG. 4, in step 401, it is determined whether the mobile communication system is operating normally. When it is determined that the mobile communication system operates normally, the process proceeds to step 403 to determine whether an erroneous operation is generated by the mobile communication system. That is, the mobile communication system receives the state information on the mobile communication system from the alarm board to check the states of the boards that constitute the mobile communication system.

When it is determined that the erroneous operation is generated by the mobile communication system, the process proceeds to step 405 to transmit a test mode change request signal from the test apparatus 210 to the board by which the erroneous operation is generated in order to check the state of the board by which the erroneous operation is generated.

Then, the process proceeds to step 407 to determine whether the board that received the test mode change request signal is changed to a test mode. Here, when the test mode change request signal is received from the test apparatus 210, the board is changed to the test mode in accordance with the control of the test mode determiner 201 included in the boards 200.

When the board is changed to the test mode, the process proceeds to step 409 to determine whether a method of testing the board is a BST verifying mode.

When it is determined that the method of testing the board is the BST verifying mode, the process proceeds to step 411 in which the BST test unit 333 of FIG. 3 connects the board to be tested and verified and a JTAG communication channel to each other to examine the internal characteristics of the board. That is, the mobile communication system selects the BST signals of the boards to be BST verified among the boards mounted in the rack to examine the internal characteristics of the boards to be BST verified.

Then, the process proceeds to step 413 to output the state information on the board to the debugging computer 230.

On the other hand, when it is determined in step 409 that the method of testing the board is not the BST verifying mode, the process proceeds to step 415 to determine whether the method of testing the board is a board verifying mode. When it is determined that the method of testing the board is not the board verifying mode, the process returns to step 409.

When it is determined that the method of testing the board is the board verifying mode, the process proceeds to step 417 to transmit the test only image suitable for the characteristic of the board to be tested and verified to the board and to test and evidence the board. That is, the mobile communication system transmits the test only image to be applied to the board among the test only images stored in the test image storage unit 323 of FIG. 3 to the board to check the operation state of the board by the test program suitable for the board characteristic. Here, the test image storage unit 323 can transmit the test only image to the corresponding board without using an additional channel by the information input and output end 203 illustrated in FIG. 2.

Then, the process proceeds to step 413 to output the state information on the board to the debugging computer 230.

As described above, when an erroneous operation is generated by the mobile communication system, the operations of the boards are verified. Also, when the user requests to test a board, the board is tested and verified by the same method.

As described above, the test apparatus including the information items and the test images required for testing the boards is added to the latticed rack of the boards in the mobile communication system so that it is possible to reduce hardware load and software load for realizing the apparatus for verifying the mobile communication system, to immediately cope with problems that occur in the mobile communication system, and to thus effectively use the mobile communication system.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. An apparatus for verifying a mobile communication system, comprising:
a test slot in which boards that constitute the mobile communication system are positioned to change the boards to a testing and verifying mode in accordance with a received test mode request signal; and
a test apparatus for transmitting a test mode change request signal to a board to be verified among the boards and for examining the internal characteristics and the operation state of the board changed to the testing and verifying mode.

2. The apparatus of claim 1, wherein the boards comprise at least one of a network synchronization board, a processor board, a link board, a MODEM block board, and an alarm board.

3. The apparatus of claim 1, wherein the test slot comprises a mode determiner for determining the operation mode of the board in accordance with a signal received from the testing and verifying apparatus to change the board to a testing and verifying mode when a test mode change request signal is received from the testing and verifying apparatus.

4. The apparatus of claim 1, wherein the test apparatus comprises:
a boundary scan test (BST) test apparatus for connecting the board to be verified and a joint test action group (JTAG) communication channel to each other to examine the internal characteristics of the board;
a board examining apparatus for transmitting a test image to the board to be verified to examine the operation state of the board; and
a switching unit for connecting the board to be verified and one of the BST test apparatus and the board examining apparatus to each other.

5. The apparatus of claim 4, wherein the BST test apparatus comprises:
a BST test unit connected to the board to be verified by a JTAG communication channel to examine the internal characteristics of the board; and
a BST connection controller for controlling connection between the BST test unit and the board.

6. The apparatus of claim 4, wherein the board examining apparatus comprises:
an image storage unit for storing test only images of the boards; and
a test controller for transmitting the test only image of a board to be verified among the test only images to the board to examine the operation state of the board.

7. The apparatus of claim 4, wherein the switching unit connects the board to be verified and one of the BST test apparatus and the board examining apparatus to each other using the JTAG communication channel.

8. The apparatus of claim 4, wherein the test apparatus further comprises a board controller for collecting the internal characteristic information and the operation state of the board to be verified to transmit the collected information and operation state.

9. A method of verifying a mobile communication system, comprising the steps of:
transmitting a test mode change request signal to a board in the mobile communication system;
determining whether the board that received the test mode change request signal is changed to a testing and verifying mode; and
examining internal characteristics and an operation state of the board in accordance with a testing and verifying method when the board is changed to the testing and verifying mode.

10. The method of claim 9, wherein the testing and verifying apparatus is connected to the board using a Joint Test Action Group (JTAG) communication channel.

11. The method of claim 10, wherein the examining step comprises connecting the board and the JTAG communication channel to each other to examine the internal characteristics of the board when the testing and verifying method is a Boundary Scan Test (BST) verifying mode.

12. The method of claim 9, wherein, when the testing and verifying method is a board verifying mode, the examining step comprises:
transmitting a test only image generated to be suitable for the characteristic of the board to the board; and
checking the operation state of the board using the test only image.

13. The method of claim 9, wherein the boards comprise at least one of a network synchronization board, a processor board, a link board, a MODEM block board, and an alarm board.

14. The method of claim 9, further comprising collecting the internal characteristic information and the operation state of the board that are checked to transmit the collected information and operation state.
